(19) United States
(12) Patent Application Publication
(10) Pub. No.: US 2013/0037952 A1
(43) Pub. Date: Feb. 14, 2013

(54) SEMICONDUCTOR PACKAGE AND METHOD FOR MANUFACTURING THE SAME

(71) Applicant: Young Berm JUNG, Cheongju-si (KR)

(72) Inventor: Young Berm JUNG, Cheongju-si (KR)

(73) Assignee: SK HYNIX INC., Icheon-si (KR)

(21) Appl. No.: 13/565,951

(22) Filed: Aug. 3, 2012

(30) Foreign Application Priority Data
Aug. 9, 2011 (KR) 10-2011-0078850
May 2, 2012 (KR) 10-2012-0046194

(51) Int. Cl. H01L 23/498; H01L 21/56

(52) U.S. Cl. 257/738; 438/107; 257/E23.069; 257/E21.504

(57) ABSTRACT

A semiconductor package includes a substrate, a driving chip module including a plurality of driving chips stacked on the substrate, and a molding part formed on the substrate by compressing a sheet type molding member in a semi-cured (B-stage) state to cover the driving chip module.

### CROSS-REFERENCES TO RELATED APPLICATIONS

The present application claims priorities under 35 U.S.C. 119(a) to Korean patent application numbers 10-2011-78850 filed in the Korean intellectual property office on Aug. 9, 2011 and 10-2012-0046194 filed in the Korean intellectual property office on May 2, 2012, which are incorporated herein by reference in their entireties.

### BACKGROUND OF THE INVENTION

1. Field of the Invention

The present invention relates to a semiconductor package, and more particularly, to a semiconductor package which can decrease the probability of a failed occurrence of operation to improve reliability and the manufacturing yield, and a method for manufacturing the same.

2. Description of the Related Art

As miniaturization and high performance are demanded from electric and electronic appliances, various stacking techniques have been developed. The term “stack” that is referred to in the semiconductor industry means to vertically pile at least two semiconductor chips or semiconductor packages. In the case of a memory device, by using stacking technology, it is possible to create a product having memory capacity that is at least two times greater than that obtained through semiconductor integration processes. Since stacked semiconductor packages have advantages in terms of memory capacity, mounting density, and mounting area utilization efficiency, research and development for stacked semiconductor packages have been seen growth.

In general, in a stacked semiconductor package, electrical connections between a substrate and semiconductor chips are implemented by connection members such as conductive wires and through electrodes. In order to protect stacked semiconductor chips, a molding part is formed through a molding process to seal the upper surface of the substrate and the stacked semiconductor chips.

A conventional molding process is performed in such a manner that, with a mold attached to a substrate having semiconductor chips stacked thereon, a molding member, which is constituted by thermosetting resin in the form of a tablet, is melted to have flowing properties, and, after the flowable molding member is introduced into the mold under pressure to fill the mold, the molding member is stiffened. However, this process likely produces voids in the molding member due to a difference in the flow rate of the molding member between where the stacked semiconductor chips are present and auxiliary areas. Further, due to the pressure applied to introduce the molding member into the mold, a lifting phenomenon is likely to occur between the semiconductor chips.

In addition, when conductive wires are used as connection members, the conductive wires are likely to either be swept by the flow of the molding member, or bend, both of which may short-circuit adjoining conductive wires or semiconductor chips. Thus, in the conventional molding process, electrical characteristics are likely to deteriorate.

### BRIEF SUMMARY OF THE INVENTION

Embodiments of the present invention are directed to a semiconductor package which can decrease the probability of a failed occurrence of operation to improve reliability and the manufacturing yield, and a method for manufacturing the same.

In an embodiment of the present invention, a semiconductor package includes a substrate, a driving chip module including a plurality of driving chips stacked on the substrate, and a molding part formed on the substrate by compressing a sheet type molding member in a semi-cured (B-stage) state to cover the driving chip module.

Each driving chip may further include bonding pads which are formed on the other surface thereof facing away from one surface facing towards the substrate, and the driving chips may be stacked in a step-like zigzag shape such that their bonding pads are exposed.

The semiconductor package may further include connection members electrically connecting the bonding pads of the respective driving chips with the substrate. The connection members may include conductive wires.

The connection members may be formed as conductive wires, and the semiconductor package may further include an adhesive member formed on an uppermost driving chip among the driving chips that fastens the conductive wires which are connected with the bonding pads of the uppermost driving chip.

The semiconductor package may further include a dummy chip attached to the adhesive member.

The adhesive member may include a P-spacer (penetrate spacer) tape, and the molding part comprises of an Epoxy Molding Compound (EMC).

In an embodiment of the present invention, a method for manufacturing a semiconductor package includes the steps of preparing a substrate, forming a driving chip module by stacking a plurality of driving chips on the substrate, and forming a molding part to cover the driving chip module by compressing a sheet type molding member in a semi-cured (B-stage) state on the substrate including the driving chip module.

The step of forming the driving chip module may be performed by stacking the driving chips such that the surfaces on which bonding pads are disposed face away from the substrate.

The step of forming the driving chip module may be performed by stacking the driving chips in a step-like zigzag shape such that the bonding pads of the respective driving chips are exposed.

After the step of forming the driving chip module and before the step of forming the molding part, the method may further include forming connection members which electrically connect the bonding pads of the respective driving chips with the substrate, and attaching an adhesive member to an uppermost driving chip of the driving chip module.

The connection members may include conductive wires, and the adhesive member may fasten the conductive wires which are connected with the bonding pads of the uppermost driving chip.

Within the step of attaching the adhesive member, the adhesive member may be provided in a state in which a dummy chip is attached to the other surface of the adhesive member facing away from the surface of the adhesive member attached to the driving chip module.

The adhesive member may include a P-spacer tape, and the molding part may include an Epoxy Molding Compound (EMC).

The step of forming the molding part may be performed using vacuum lamination equipment which includes a mounting table and a compression table.

Within the step of forming the molding part, the mounting table may be placed under the substrate, and the compression table may be placed over the molding part.

Implementing the above embodiments, in contrast to the conventional art in which a molding part is formed in such a manner that a molding member in the form of a tablet is melted and introduced into a mold under pressure to fill the mold, in the present invention, a molding member in the form of a sheet in a semi-cured (B-stage) state is molded using heat, compression, and vacuum via a vacuum lamination equipment, whereby it is possible to prevent both incomplete filling of the molding part and lifting of semiconductor chips.

In the embodiments of the present invention, because an adhesive member is formed on an uppermost semiconductor chip and the conductive wires connected to the uppermost driving chip can be stably fastened, sweeping and bending of the conductive wires are suppressed, whereby it is possible to prevent a failed occurrence of operation, such as a short-circuit between the conductive wires and a short-circuit between the conductive wires and the semiconductor chips.

### BRIEF DESCRIPTION OF THE DRAWINGS

FIG. 1 is a cross-sectional view illustrating a semiconductor package in accordance with an embodiment of the present invention.

FIGS. 2A to 2D are cross-sectional views explaining a method for manufacturing a semiconductor package in accordance with an embodiment of the present invention.

FIG. 3 is a perspective view illustrating an electronic apparatus having the semiconductor package according to the present invention.

FIG. 4 is a block diagram showing an example of an electronic system including the semiconductor package according to the present invention.

### DESCRIPTION OF SPECIFIC EMBODIMENTS

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

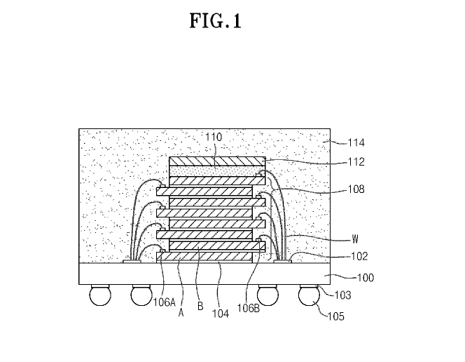

FIG. 1 is a cross-sectional view illustrating a semiconductor package in accordance with an embodiment of the present invention.

Referring to FIG. 1, the semiconductor package in accordance with an embodiment of the present invention includes a substrate 100, a driving chip module 108, and a molding part 114. The semiconductor package further includes an adhesive member 110, a dummy chip 112, and external connection terminals 105.

The substrate 100 has one surface and the other surface which faces away from the one surface. Bond fingers 102 are formed on the one surface of the substrate 100, and ball lands 103 are formed on the other surface of the substrate 100. The substrate 100 may be, for example, a printed circuit board. The external connection terminals 105 are mounted to the ball lands 103 of the substrate 100. The external connection terminals 105 may include solder balls.

The driving chip module 108 is disposed on the one surface of the substrate 100 and has a structure in which at least two first and second driving chips A and B are alternately stacked.

The substrate 100 and the driving chip module 108 are adhered to each other, and the first driving chip A and the second driving chip B are adhered to each other, by using adhesive members 104 which are formed between the substrate 100 and the driving chip module 108, and between the first driving chip A and the second driving chip B, respectively.

The first driving chip A has one surface which faces the substrate 100, the other surface which faces away from the one surface, and first bonding pads 106A which are formed on the other surface of the first driving chip A.

The second driving chip B has one surface which faces the substrate 100, the other surface which faces away from the one surface, and second bonding pads 106B which are formed on the other surface of the second driving chip B.

It is desired that the second bonding pads 106B is formed at positions opposite to the first bonding pads 106A of the first driving chip A. In other words, when viewing the cross-section, in the case where the first bonding pads 106A are formed on the left of the first driving chip A, the second bonding pads 106B are formed on the right of the second driving chip B.

In the present embodiment, the first and second driving chips A and B are stacked in a step-like zigzag shape such that the first and second bonding pads 106A and 106B are exposed.

The first and second bonding pads 106A and 106B of the first and second driving chips A and B are electrically connected with the bond fingers 102 of the substrate 100 by connection members W, such as conductive wires for example.

The adhesive member 110 is formed on a driving chip, hereinafter referred to as an uppermost driving chip, positioned uppermost among the driving chips included in the driving chip module 108, in such a way as to accommodate portions of the conductive wires connected with the bonding pads of the uppermost driving chip to thereby fasten the conductive wires. The adhesive member 110 may include, for example, a P-spacer (penetrate spacer) tape.

The P-spacer tape is an adhesive tape which may adhere chips to each other, a chip and a substrate to each other, or may be independently adhered onto a chip or a substrate. While adhering the P-spacer tape onto a chip or a substrate, the wires on the chip or the substrate penetrates into the P-spacer tape, and the fastening therein prevents the occurrence of sweeping that may otherwise occur in a manufacturing procedure.

The dummy chip 112 is attached onto the adhesive member 110.

The molding part 114 is formed by compressing a sheet type molding member in a semi-cured (B-stage) state to cover the driving chip module 108 on the substrate 100. The molding part 114 may include an Epoxy Molding Compound (EMC).

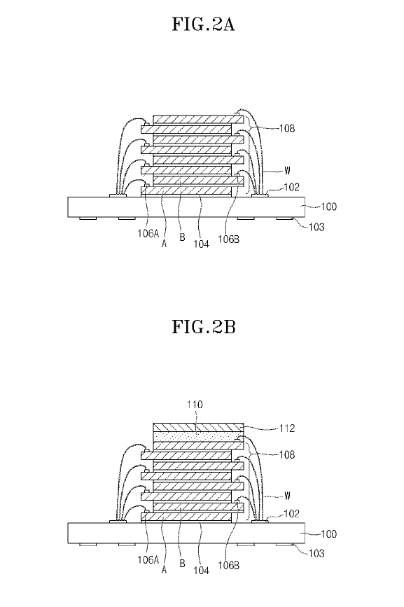

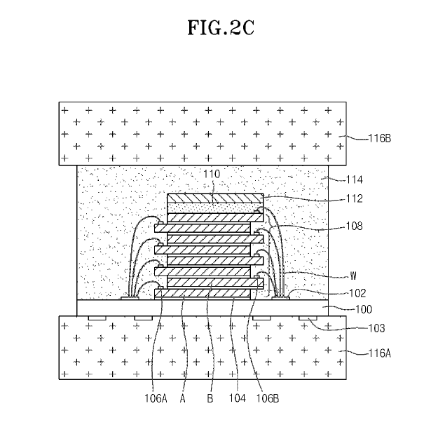

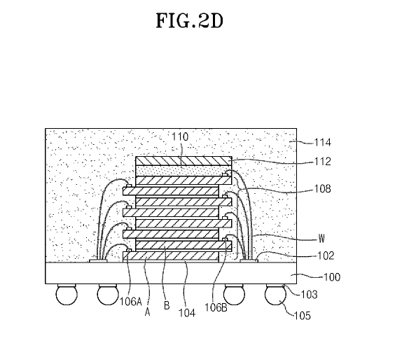

Hereafter, a method for manufacturing the semiconductor package in accordance with the embodiment of the present invention will be described with reference to FIGS. 2A to 2D.

FIGS. 2A to 2D are cross-sectional views explaining a method for manufacturing a semiconductor package in accordance with an embodiment of the present invention.

First, referring to FIG. 2A, after preparing a substrate 100 which has one surface and the other surface facing away from the one surface, and possessing bond fingers 102 on the one surface and ball lands 103 on the other surface, a driving chip module 108 is disposed on the one surface of the substrate 100.

The driving chip module 108 may be formed by alternately stacking at least two first and second driving chips A and B via adhesive members 104 on the substrate 100

The first driving chip A has one surface and the other surface facing away from the one surface, and possesses first bonding pads 106A on the other surface of the first driving chip A. The second driving chip B has one surface and the other surface facing away from the one surface, and possesses second bonding pads 106B on the other surface of the second driving chip B.

The first and second driving chips A and B may be stacked in a face-up type manner in such a way that their respective one surfaces face the substrate 100 in a step-like zigzag shape such that the first and second bonding pads 106A and 106B are exposed.

The bond fingers 102 of the substrate 100 and the first and second bonding pads 106A and 106B of the first and second driving chips A and B are electrically connected with each other via conductive wires W.

Referring to FIG. 2B, an adhesive member 110 is attached to the uppermost driving chip of the driving chip module 108. The adhesive member 110 is provided in a state in which a dummy chip 112 is attached to the other surface of the adhesive member 110 facing away from one surface of the adhesive member 110 which is attached to the driving chip module 108. Although not shown, only the adhesive member 110 may be attached to the driving chip module 108 without the dummy chip 112.

The adhesive member 110 is formed to accommodate portions of the conductive wires which are connected to the bonding pads of the uppermost driving chip and thereby fastened. The adhesive member 110 may include a P-spacer tape.

Referring to FIG. 2C, a molding part 114 is formed by compressing a molding member in the form of a sheet in a semi-cured (B-stage) state, on the substrate 100 including the driving chip module 108 and the dummy chip 112. The molding member is compressed on the substrate 100 using heat, compression, and vacuum via vacuum lamination equipment including a mounting table 116A and a compression table 116B.

The mounting table 116A is placed under the substrate 100 and functions to fix the substrate 100 and compress the molding member. The compression table 116B is placed over the molding part 114 and functions to compress the molding member in cooperation with the mounting table 116A. Although not shown in the drawing, moving units for moving the mounting and compression tables 116A and 116B upward and downward are provided to the mounting and compression tables 116A and 116B.

Referring to FIG. 2D, by mounting external connection terminals 105 to the ball lands 103 of the substrate 100, the manufacture of the semiconductor package according to the embodiment of the present invention is completed.

The aforementioned semiconductor package may be applied to various electronic apparatuses.

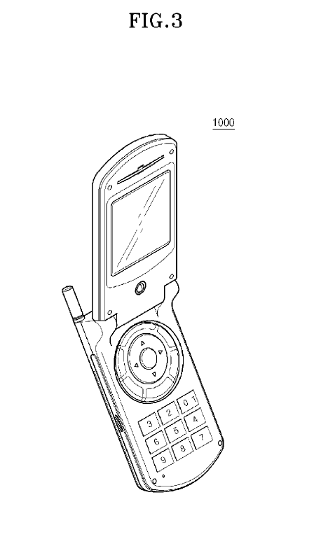

FIG. 3 is a perspective view illustrating an electronic apparatus having the semiconductor package according to the present invention.

Referring to FIG. 3, the semiconductor package according to the embodiment of the present invention may be applied to an electronic apparatus 1000 such as a mobile phone. Because the semiconductor package according to the embodiment of the present invention can decrease the probability of a failed occurrence of operation, advantages are provided in improving the reliability of the electronic apparatus 1000. The electronic apparatus 1000 is not limited to the mobile phone shown in FIG. 3, and may include various electronic appliances such as a mobile electronic appliances, laptop computers, notebook computers, portable multimedia players (PMP), MP3 players, camcorders, web tablets, wireless phones, navigators, personal digital assistants (PDA), and so forth.

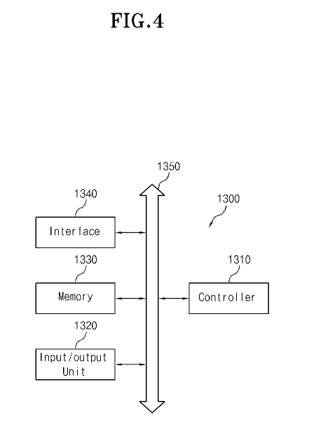

FIG. 4 is a block diagram showing an example of an electronic system including the semiconductor package according to the present invention.

Referring to FIG. 4, an electronic system 1300 may include a controller 1310, an input/output unit 1320, and a memory 1330. The controller 1310, the input/output unit 1320, and the memory 1330 may be coupled with one another through a bus 1350. The bus 1350 may be understood to be a path through which data flows. For example, the controller 1310 may include at least any one of microprocessors, digital signal processors, microcontrollers, and logic devices capable of performing the same functions as these components. The controller 1310 and the memory 1330 may include the semiconductor package according to the embodiment of the present invention. The input/output unit 1320 may include at least any one of keypads, keyboards, display devices, and so forth. The memory 1330 is a device for storing data. The memory 1330 may store data and/or commands to be executed by the controller 1310, and so forth. The memory 1330 may include a volatile memory device and/or a nonvolatile memory device. Also, the memory 1330 may be formed as a flash memory. For example, a flash memory to which the technology of the present invention is applied may be mounted to an information processing system such as a mobile appliance or a desktop computer. The flash memory may be constituted by a solid state drive (SSD). In this case, the electronic system 1300 may stably store a large amount of data in a flash memory system. The electronic system 1300 may further include an interface 1340 configured to transmit and receive data to and from a communication network. The interface 1340 may be of a wired or wireless type. For example, the interface 1340 may include an antenna or a wired or wireless transceiver. Moreover, a person skilled in the art will readily appreciate that the electronic system 1300 may be additionally provided with an application chipset, a camera image processor (CIP), an input/output device, etc.

As is apparent from the above description, in contrast to the conventional art in which a molding part is formed in such a manner that a molding member in the form of a tablet is melted and introduced into a mold under pressure to fill the mold, in the embodiments of the present invention, a molding member in the form of a sheet in a semi-cured B-stage is molded using heat, compression, and vacuum via a vacuum lamination equipment, whereby it is possible to prevent both incomplete filling of the molding part and lifting of semiconductor chips.

In the embodiments of the present invention, because an adhesive member is formed on an uppermost semiconductor chip and the conductive wires connected to the uppermost driving chip can be stably fastened, sweeping and bending of the conductive wires are suppressed, whereby it is possible to prevent a failed occurrence of operation such as a short-circuit between the conductive wires and a short-circuit between the conductive wires and the semiconductor chips.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor package comprising:
a substrate;
a driving chip module including a plurality of driving chips stacked on the substrate; and
a molding part formed on the substrate by compressing a sheet type molding member in a semi-cured (B-stage) state to cover the driving chip module.

2. The semiconductor package according to claim 1,
wherein each driving chip has bonding pads which are formed on the other surface thereof facing away from one surface facing towards the substrate, and
wherein the driving chips are stacked in a step-like zigzag shape such that their bonding pads are exposed.

3. The semiconductor package according to claim 2, further comprising:
connection members electrically connecting the bonding pads of the respective driving chips with the substrate.

4. The semiconductor package according to claim 3, wherein the connection members comprise conductive wires.

5. The semiconductor package according to claim 3,
wherein the connection members are formed as conductive wires, and
wherein the semiconductor package further comprises:
an adhesive member formed on an uppermost driving chip among the driving chips that fastens the conductive wires which are connected with the bonding pads of the uppermost driving chip.

6. The semiconductor package according to claim 5, further comprising:
a dummy chip attached to the adhesive member.

7. The semiconductor package according to claim 6, wherein the adhesive member comprises a penetrate spacer (P-spacer) tape.

8. The semiconductor package according to claim 1, wherein the molding part comprises of an epoxy molding compound (EMC).

9. The semiconductor package according to claim 1, further comprising a plurality of external connection terminals via a plurality of ball lands on the bottom surface of the substrate.

10. A method for manufacturing a semiconductor package, comprising the steps of:
preparing a substrate;
stacking a plurality of driving chips on the substrate and forming a driving chip module; and
forming a molding part to cover the driving chip module, by compressing a sheet type molding member in a semi-cured (B-stage) state on the substrate including the driving chip module.

11. The method according to claim 10, wherein the step of forming the driving chip module is performed by stacking the driving chips such that the surfaces on which bonding pads are disposed face away from the substrate.

12. The method according to claim 11, wherein the step of forming the driving chip module is performed by stacking the driving chips in a step-like zigzag shape such that the bonding pads of the respective driving chips are exposed.

13. The method according to claim 12, wherein, after the step of forming the driving chip module and before the step of forming the molding part, the method further comprises:
forming connection members which electrically connect the bonding pads of the respective driving chips with the substrate; and
attaching an adhesive member to an uppermost driving chip of the driving chip module.

14. The method according to claim 13, wherein the connection members comprise of conductive wires, and the adhesive member fastens the conductive wires which are connected with the bonding pads of the uppermost driving chip.

15. The method according to claim 13, wherein, within the step of attaching the adhesive member, the adhesive member is provided in a state in which a dummy chip is attached to the other surface of the adhesive member facing away from the surface of the adhesive member attached to the driving chip module.

16. The method according to claim 13, wherein the adhesive member comprises a penetrate spacer (P-spacer) tape.

17. The method according to claim 10, wherein the molding part comprises an epoxy molding compound.

18. The method according to claim 10, wherein the step of forming the molding part is performed using vacuum lamination equipment which includes a mounting table and a compression table.

19. The method according to claim 18, wherein, in the step of forming the molding part, the mounting table is placed under the substrate, and the compression table is placed over the molding part.

20. The method according to claim 9, further comprising:
mounting a plurality of external connection terminals via a plurality of ball lands on the bottom surface of the substrate.
